(19) United States
(12) Patent Application Publication
(10) Pub. No.: US 2007/0090508 A1
(43) Pub. Date: Apr. 26, 2007

(54) Multi-chip package structure

(76) Inventors: Chian-Chi Lin, Kaohsiung (TW); Cheng-Yin Lee, Kaohsiung (TW)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/520,769

(22) Filed: Sep. 14, 2006

(30) Foreign Application Priority Data
Oct. 26, 2005 (TW) 094137529
Apr. 28, 2006 (TW) 095115343

(51) Int. Cl. H01L 23/02

(52) U.S. Cl. 257/686

(57) ABSTRACT

The present invention relates to a multi-chip package structure, which comprises a first substrate, a first chip, a sub-package structure, a plurality of first solder balls, and a first molding compound. The first substrate has a first surface and a second surface. The first chip is electrically connected to the first surface of the first substrate. The sub-package structure comprises a second substrate, a second chip, and a second molding compound. The first solder balls are disposed between the first substrate and the second substrate and are used for connecting the first surface of the first substrate and the second surface of the second substrate so as to omit a step of wire bonding.

### BACKGROUND OF THE INVENTION

1. Field of the Invention

The present invention relates to a semiconductor package structure, and more particularly, to a package structure containing a sub-package structure.

2. Description of the Related Art

Referring to FIG. 1, a schematic view of a conventional multi-chip package structure disclosed in U.S. Pat. No. 6,838,761 is shown. The conventional multi-chip package structure 1 comprises a first substrate 11, a first chip 12, a first adhesive 13, a plurality of first connecting wires 14, a first molding compound 15, a sub-package structure 2, a third adhesive 16, a plurality of third connecting wires 17, a third molding compound 18, a heat spreader 19, and a plurality of solder balls 20. The first substrate 11 has an upper surface 111 and a lower surface 112. The first chip 12 is adhered to the upper surface 111 of the first substrate 11 by using the first adhesive 13. The first connecting wires 14 are electrically connected to the first chip 12 and the upper surface 111 of the first substrate 11. The first molding compound 15 encapsulates the first chip 12, the first connecting wires 14, and a part of the upper surface 111 of the first substrate 11, and the first molding compound 15 has an upper surface 151.

The sub-package structure 2 comprises a second substrate 21, a second chip 22, a second adhesive 23, a plurality of second connecting wires 24, and a second molding compound 25. The second substrate 21 has an upper surface 211 and a lower surface 212. The second chip 22 is adhered to the upper surface 21 of the second substrate 21 by using the second adhesive 23. The second connecting wires 24 are electrically connected to the second chip 22 and the upper surface 211 of the second substrate 21. The second molding compound 25 encapsulates the second chip 22, the second connecting wires 24, and a part of the upper surface 211 of the second substrate 21.

The sub-package structure 2 is stacked on the upper surface 151 of the first molding compound 15, and the lower surface 212 of the second substrate 21 is adhered to the upper surface 151 of the first molding compound 15 by using the third adhesive 16. The second substrate 21 is electrically connected to the upper surface 111 of the first substrate 11 by the third connecting wires 17. The third molding compound 18 encapsulates the sub-package structure 2, the first molding compound 15, and the upper surface 111 of the first substrate 11. The heat spreader 19 has a body 191 and a supporting portion 192, wherein the supporting portion 192 extends downward from the body 191 to the outside, so as to support the body 191. The body 191 is exposed outside the third molding compound 18. The solder balls 20 are disposed at the lower surface 112 of the first substrate 11 for providing a connection to an external device.

The disadvantage of the conventional multi-chip package structure 1 lies in that since the third connecting wires 17 are electrically connected to the second substrate 21 and the first substrate 11, when the sub-package structure 2 is adhered to the upper surface 151 of the first molding compound 15, the outer side of the second substrate 21 is suspended, thus increasing the operation difficulty of wire bonding. In addition, the first chip 12 is electrically connected to the upper surface 111 of the first substrate 11 through the first connecting wires 14, such that the first chip 12 and the first connecting wires 14 must be first coated with the first molding compound 15, and then stacked on the sub-package structure 2. Therefore, a molding is additionally added, and also the overall height is increased.

Therefore, it is necessary to provide a multi-chip package structure to solve the above problems.

### SUMMARY OF THE INVENTION

The objective of the present invention is to provide a multi-chip package structure, which comprises a first substrate, a first chip, a sub-package structure, a plurality of first solder balls, and a first molding compound. The first substrate has a first surface and a second surface. The first chip is electrically connected to the first surface of the first substrate. The sub-package structure comprises a second substrate, a second chip, and a second molding compound. The first solder balls are disposed between the first substrate and the second substrate and are used for connecting the first surface of the first substrate to the second surface of the second substrate. The first molding compound encapsulates the first chip, the sub-package structure, the first solder balls, and a part of the first surface of the first substrate. The first substrate and the second substrate are connected to each other by the first solder balls, and thus a step of wire bonding is omitted.

### BRIEF DESCRIPTION OF THE DRAWINGS

FIG. 1 is a schematic view of a conventional multi-chip package structure disclosed in U.S. Pat. No. 6,838,761;

FIG. 2 is a schematic sectional view of a multi-chip package structure according to the first embodiment of the present invention;

FIGS. 3a-3f are schematic views of a manufacturing flow according to the first embodiment of FIG. 2;

FIG. 4 is a schematic sectional view of a multi-chip package structure according to the second embodiment of the present invention;

FIG. 5 is a schematic sectional view of a multi-chip package structure according to the third embodiment of the-present invention;

FIG. 6 is a schematic sectional view of a multi-chip package structure according to the fourth embodiment of the present invention;

FIG. 7 is a schematic sectional view of a multi-chip package structure according to the fifth embodiment of the present invention;

FIG. 8 is a schematic sectional view of a multi-chip package 5 structure according to the sixth embodiment of the present invention; and

FIG. 9 is a schematic sectional view of a multi-chip package structure according to the seventh embodiment of the present invention.

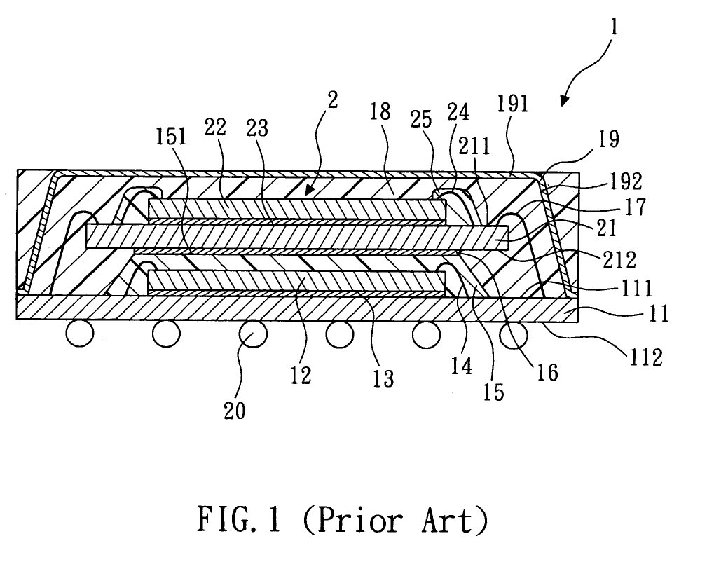

### DETAILED DESCRIPTION OF THE INVENTION

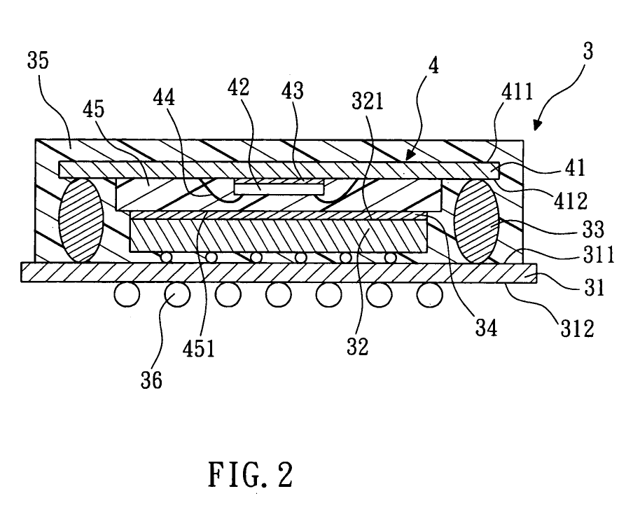

Referring to FIG. 2, a schematic sectional view of a multi-chip package structure according to the first embodiment of the present invention is shown. The multi-chip package structure 3 comprises a first substrate 31, a first chip 32, a sub-package structure 4, a plurality of first solder balls 33, a first adhesive 34, a first molding compound 35, and a plurality of second solder balls 36. The first substrate 31 has a first surface 311 (upper surface) and a second surface 312 (lower surface). The first chip 32 is bonded to the first surface 311 of the first substrate 31 in a flip-chip manner, and the first chip 32 has a first surface 321 (upper surface).

The first chip 32 comprises, but is not limited to, a digital chip, an analog chip, an optical chip, a logic chip, a micro-processing chip, and a memory chip.

The sub-package structure 4 comprises a second substrate 41, a second chip 42, a second adhesive 43, a plurality of second connecting wires 44, and a second molding compound 45. The second substrate 41 has a first surface 411 (upper surface) and a second surface 412 (lower surface). The second chip 42 is adhered to the second surface 412 of the second substrate 41 by using the second adhesive 43. The second chip 42 comprises, but is not limited to, a digital chip, an analog chip, an optical chip, a logic chip, a micro-processing chip, and a memory chip. The second connecting wires 44 are used to electrically connect the second chip 42 and the second surface 412 of the second substrate 41. The second molding compound 45 encapsulates a part of the second chip 42, the second connecting wires 44, and a part of the second surface 412 of the second substrate 41, and the second molding compound 45 has a second surface 451 (lower surface).

The sub-package structure 4 is stacked on the first surface 321 of the first chip 32, and the second surface 451 of the second molding compound 45 is adhered to the first surface 321 of the first chip 32 by using the first adhesive 34. The first solder balls 33 are disposed between the first substrate 31 and the second substrate 41, and are used to physically and electrically connect the first surface 311 of the first substrate 31 and the second surface 412 of the second substrate 41. The first molding compound 35 encapsulates the first chip 32, the sub-package structure 4, the first solder balls 33, and a part of the first surface 311 of the first substrate 31. The second solder balls 36 are formed on the second surface 312 of the first substrate 31, and are used for connecting an external device.

The first chip 32 is bonded to the first surface 311 of the first substrate 31 by flip-chip bonding, and thus a step of wire bonding is omitted, and the overall height of the multi-chip package structure 3 is reduced. Moreover, the first substrate 31 and the second substrate 41 are connected to each other by the first solder balls 33, and thus a step of wire bonding can be further omitted.

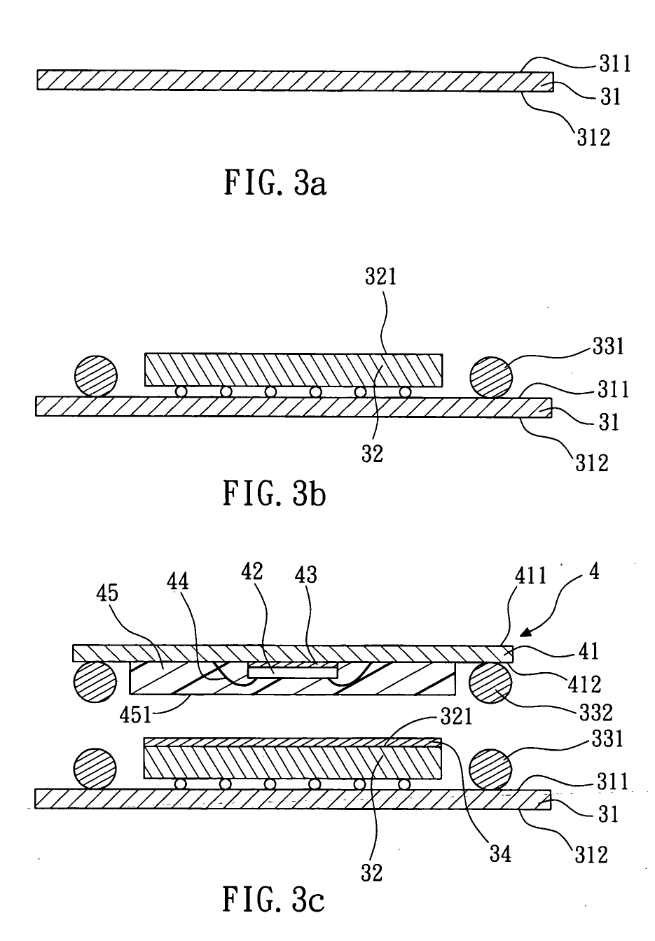

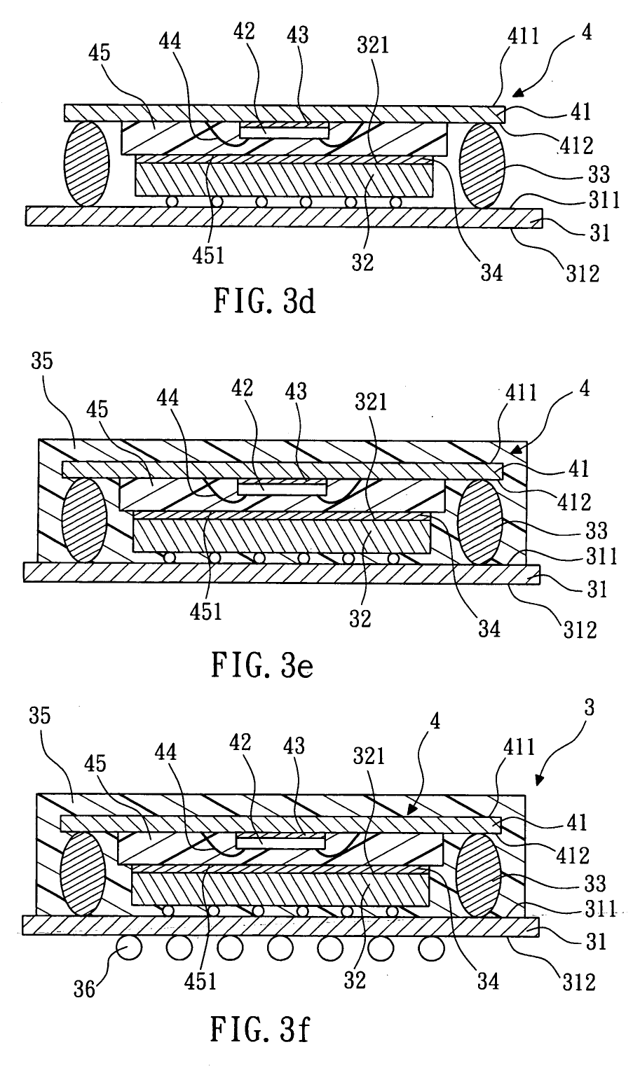

Referring to FIGS. 3a-3f, schematic views of a manufacturing flow according to the first embodiment of FIG. 2 are shown. First, referring to FIG. 3a, a first substrate 31 is provided, which has a first surface 311 and a second surface 312. Then, referring to FIG. 3b, a plurality of third solder balls 331 is formed on the first surface 311 of the first substrate 31, and a first chip 32 is bonded to the first surface 311 of the first substrate 31 by flip-chip bonding. The first chip 32 has a first surface 321.

Next, referring to FIG. 3c, an adhesive 34 is formed on the first surface 321 of the first chip 32, and a sub-package structure 4 is provided. The sub-package structure 4 must be tested first, and after being confirmed to be a good die, the subsequent packaging process is performed. In the present embodiment, the sub-package structure 4 comprises a second substrate 41, a second chip 42, a second adhesive 43, a plurality of second connecting wires 44, and a second molding compound 45. The second substrate 41 has a first surface 411 (upper surface) and a second surface 412 (lower surface). The second chip 42 is adhered to the second surface 412 of the second substrate 41 by using the second adhesive 43. The second connecting wires 44 are used to electrically connect the second chip 42 and the second surface 412 of the second substrate 41. The second molding compound 45 encapsulates a part of the second chip 42, the second connecting wires 44, and a part of the second surface 412 of the second substrate 41, and the second molding compound 45 has a second surface 451 (lower surface). The sub-package structure 4 further comprises a plurality of fourth solder balls 332 disposed on the second surface 412 of the second substrate 41 not being encapsulated by the second molding compound 45.

Then, referring to FIG. 3d, the sub-package structure 4 is stacked on the first surface 321 of the first chip 32, and the second surface 451 of the second molding compound 45 is adhered to the first surface 321 of the first chip 32 by using the adhesive 34. After the third solder balls 331 contact the fourth solder balls 332, the third solder balls 331 and the fourth solder balls 332 are subjected to a reflowing step and melted to form a plurality of first solder balls 33.

Then, referring to FIG. 3e, a first molding compound 35 is formed to encapsulate the first chip 32, the sub-package structure 4, the first solder balls 33, and a part of the first surface 311 of the first substrate 31.

Then, referring to FIG. 3f, a plurality of second solder balls 36 is formed on the second surface 312 of the first substrate 31, and are used for connecting to an external device.

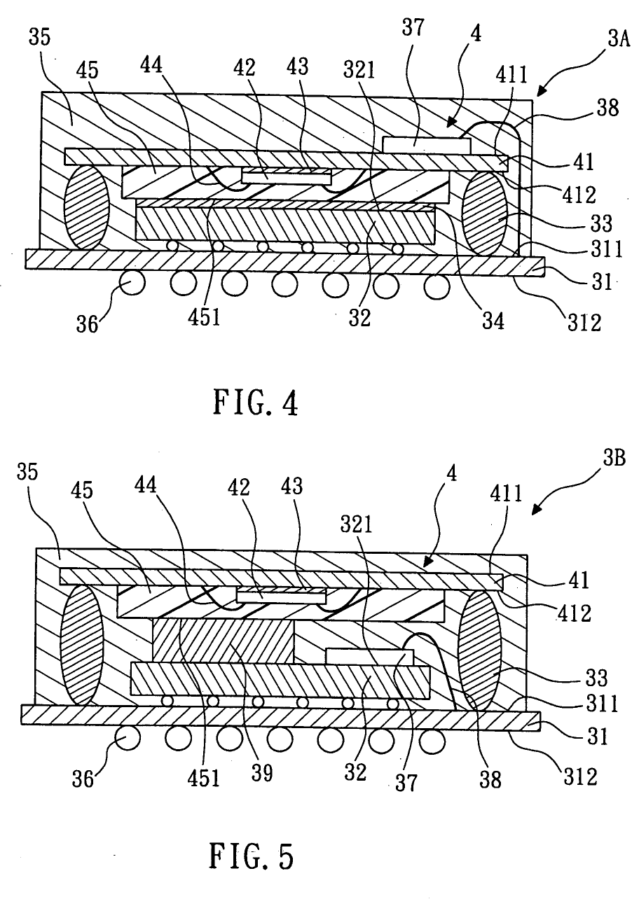

Referring to FIG. 4, a schematic sectional view of a multi-chip package structure according to the second embodiment of the present invention is shown. The difference between the multi-chip package structure 3A in the present embodiment and the multi-chip package structure 3 in the first embodiment lies in that a third chip 37 is further comprised in the multi-chip package structure 3A of the present embodiment, which is disposed on the first surface 411 of the second substrate 41 of the sub-package structure 4. The third chip 37 is electrically connected to the first surface 311 of the first substrate 31 by a plurality of first connecting wires 38. The third chip 37 comprises, but is not limited to, a digital chip, an analog chip, an optical chip, a logic chip, a micro-processing chip, and a memory chip.

Referring to FIG. 5, a schematic sectional view of a multi-chip package structure according to the third embodiment of the present invention is shown. The difference between the multi-chip package structure 3B in the present embodiment and the multi-chip package structure 3 in the first embodiment lies in that a third chip 37 and a spacer 39 are further comprised in the multi-chip package structure 3B of the present embodiment, and both the third chip 37 and spacer 39 are disposed on the first surface 321 of the first chip 32. The thickness of the spacer 39 is larger than that of the third chip 37. The second surface 451 of the second molding compound 45 is adhered to the spacer 39. The third chip 37 is electrically connected to the first surface 311 of the first substrate 31 by a plurality of first connecting wires 38.

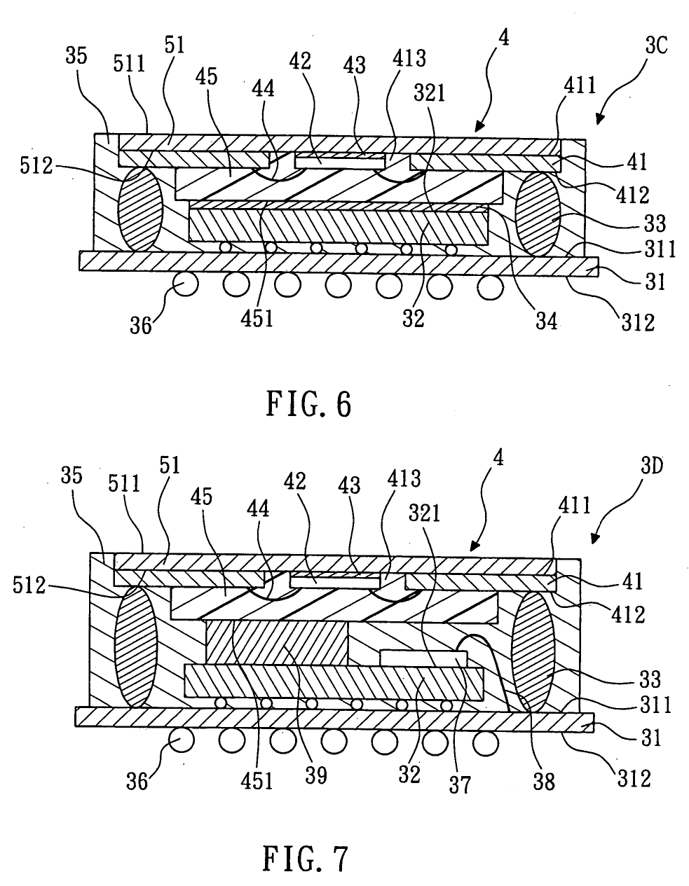

Referring to FIG. 6, a schematic sectional view of a multi-chip package structure according to the fourth embodiment of the present invention is shown. The difference between the multi-chip package structure 3C in the present embodiment and the multi-chip package structure 3 in the first embodiment is the type of the second substrate 41 of the sub-package structure 4. In the present embodiment, the second substrate 41 further comprises an opening 413, and the second chip 42 is disposed in the opening 413. In addition, the multi-chip package structure 3C in the present embodiment further comprises a heat spreader 51 which has a first surface 511 (upper surface) and a second surface 512 (lower surface). The second surface 512 of the heat spreader 51 is adhered to the first surface 411 of the second substrate 41, and the second chip 42 is adhered to the second surface 512 of the heat spreader 51. Preferably, the first surface 511 of the heat spreader 51 is exposed outside the first molding compound 35 for dissipating heat.

Referring to FIG. 7, a schematic sectional view of a multi-chip package structure according to the fifth embodiment of the present invention is shown. The difference between the multi-chip package structure 3D in the present embodiment and the multi-chip package structure 3C of the fourth embodiment lies in that the multi-chip package structure 3D in the present embodiment further comprises a third chip 37 and a spacer 39 which are disposed on the first surface 321 of the first chip 32. The thickness of the spacer 39 is larger than that of the third chip 37. The second surface 451 of the second molding compound 45 is adhered to the spacer 39. The third chip 37 is electrically connected to the first surface 311 of the first substrate 31 by a plurality of first connecting wires 38.

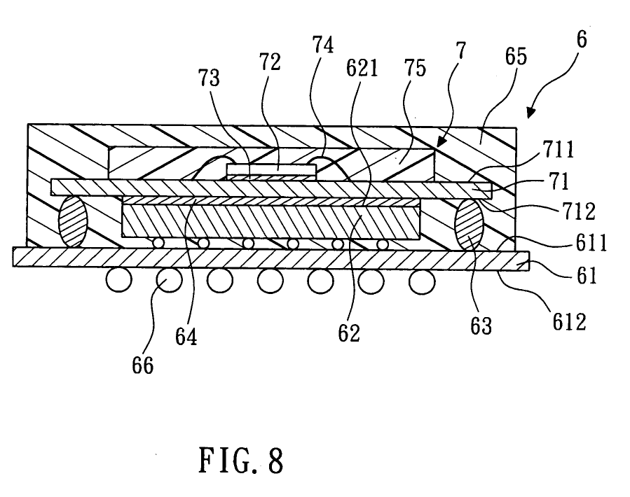

Referring to FIG. 8, a schematic sectional view of a multi-chip package structure according to the sixth embodiment of the present invention is shown. The multi-chip package structure 6 comprises a first substrate 61, a first chip 62, a sub-package structure 7, a plurality of first solder balls 63, a first adhesive 64, a first molding compound 65, and a plurality of second solder balls 66. The first substrate 61 has a first surface 611 (upper surface) and a second surface 612 (lower surface). The first chip 62 is bonded to the first surface 611 of the first substrate 61 in a flip-chip manner, and the first chip 62 has a first surface 621 (upper surface). The first chip 62 comprises, but is not limited to, a digital chip, an analog chip, an optical chip, a logic chip, a micro-processing chip, and a memory chip.

The sub-package structure 7 comprises a second substrate 71, a second chip 72, a second adhesive 73, a plurality of second connecting wires 74, and a second molding compound 75. The second substrate 71 has a first surface 711 (upper surface) and a second surface 712 (lower surface). The second chip 72 is adhered to the first surface 711 of the second substrate 71 by using the second adhesive 73. The second chip 72 comprises, but is not limited to, a digital chip, an analog chip, an optical chip, a logic chip, a micro-processing chip, and a memory chip. The second connecting wires 74 are used to electrically connect the second chip 72 and the first surface 711 of the second substrate 71. The second molding compound 75 is coated on a part of the second chip 72, the second connecting wires 74, and a part of the first surface 711 of the second substrate 71.

The sub-package structure 7 is stacked on the first surface 621 of the first chip 62, and the second surface 712 of the second substrate 71 is adhered to the first surface 621 of the first chip 62 by using the first adhesive 64. The first solder balls 63 are disposed between the first substrate 61 and the second substrate 71, and are physically and electrically connected to the first surface 611 of the first substrate 61 and the second surface 712 of the second substrate 71. The first molding compound 65 is coated on the first chip 62, the sub-package structure 7, the first solder balls 63, and a part of the first surface 611 of the first substrate 61. The second solder balls 66 are formed on the second surface 612 of the first substrate 61, and are used for connecting to an external device.

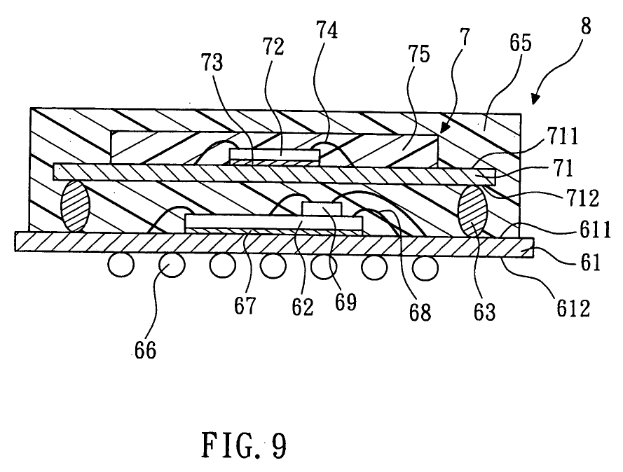

Referring to FIG. 9, a schematic sectional view of a multi-chip package structure according to the seventh embodiment of the present invention is shown. The same elements in the multi-chip package structure 8 in the present embodiment and the multi-chip package structure 6 (FIG. 8) in the sixth embodiment are indicated by the same numerals. The difference between the multi-chip package structure 8 of the present embodiment and the multi-chip package structure 6 (FIG. 8) in the sixth embodiment lies in that the first chip 62 in the present embodiment is bonded to the first surface 611 (upper surface) of the first substrate 61 in the wire bonding manner, i.e., the first chip 62 is adhered to the first surface 611 of the first substrate 61 by using an adhesive 67, and is electrically connected to the first surface 611 of the first substrate 61 by a plurality of first connecting wires 68. Preferably, the multi-chip package structure 8 further comprises a third chip 69 disposed on the first chip 62, wherein the third chip 69 is electrically connected to the first substrate 61 and the first chip 62. The third chip 69 comprises, but is not limited to, a digital chip, an analog chip, an optical chip, a logic chip, a micro-processing chip, and a memory chip.

While several embodiments of the present invention have been illustrated and described, various modifications and improvements can be made by those skilled in the art. The embodiments of the present invention are therefore described in an illustrative but not restrictive sense. It is intended that the present invention may not be limited to the particular forms as illustrated, and that all modifications which maintain the spirit and scope of the present invention are within the scope as defined in the appended claims.

What is claimed is:

1. A multi-chip package structure, comprising:
a first substrate, having a first surface and a second surface;
a first chip, electrically connected to the first surface of the first substrate;
a sub-package, comprising:
a second substrate, having a first surface and a second surface;
a second chip, electrically connected to the second substrate; and
a second molding compound, encapsulating the second chip and a part of the second substrate;
a plurality of first solder balls, disposed between the first substrate and the second substrate, and connected to the first surface of the first substrate and the second surface of the second substrate; and
a first molding compound, encapsulating the first chip, the sub-package, the first solder balls, and a part of the first surface of the first substrate.

2. The package structure according to claim 1, wherein the first chip is bonded to the first surface of the first substrate by flip-chip bonding.

3. The package structure according to claim 1, wherein the first chip is bonded to the first surface of the first substrate by wire bonding.

4. The package structure according to claim 1, wherein the sub-package structure further comprises a second adhesive for adhering the second chip to the second surface of the second substrate.

5. The package structure according to claim 4, further comprising a heat spreader having a first surface and a second surface, wherein the second surface of the heat spreader is adhered to the first surface of the second substrate.

6. The package structure according to claim 5, wherein the first surface of the heat spreader is exposed outside the first molding compound.

7. The package structure according to claim 4, wherein the first chip has a first surface, the second molding compound has a second surface, and the second surface of the second molding compound is adhered to the first surface of the first chip by using a first adhesive.

8. The package structure according to claim 4, wherein the first chip has a first surface, the second molding compound has a second surface, a spacer is disposed between the second surface of the second molding compound and the first surface of the first chip, and the package structure further comprises a third chip disposed on the first surface of the first chip and is electrically connected to the first substrate by a plurality of first connecting wires.

9. The package structure according to claim 1, wherein the sub-package structure further comprises a second adhesive for adhering the second chip on the first surface of the second substrate.

10. The package structure according to claim 1, wherein the sub-package structure further comprises a plurality of second connecting wires for electrically connecting the second substrate and the second chip.

11. The package structure according to claim 1, wherein the second substrate further comprises an opening, the second chip being disposed in the opening.

12. The package structure according to claim 1, further compring a third chip disposed on the first surface of the second substrate, the third chip electrically connected to the first substrate by a plurality of first connecting wires.

13. The package structure according to claim 1, further comprising a plurality of second solder balls formed on the second surface of the first substrate.

14. The package structure according to claim 1, wherein the first chip is selected from a group consisting of a digital chip, an analog chip, an optical chip, a logic chip, a micro-processing chip, and a memory chip.

15. The package structure according to claim 1, wherein the second chip is selected from a group consisting of a digital chip, an analog chip, an optical chip, a logic chip, a micro-processing chip, and a memory chip.

16. The package structure according to claim 3, further comprising a third chip disposed on the first chip.
